(19) United States
(12) Patent Application Publication
(10) Pub. No.: US 2013/0139022 A1
(43) Pub. Date: May 30, 2013

(54) Variable Sector Size LDPC Decoder

(71) Applicants: Lei Chen, Santa Clara, CA (US); Yang Han, Sunnyvale, CA (US); Zongwang Li, Santa Clara, CA (US); Shaohua Yang, San Jose, CA (US)

(72) Inventors: Lei Chen, Santa Clara, CA (US); Yang Han, Sunnyvale, CA (US); Zongwang Li, Santa Clara, CA (US); Shaohua Yang, San Jose, CA (US)

(73) Assignee: LSI Corporation

(21) Appl. No.: 13/305,510

(22) Filed: Nov. 28, 2011

(51) Int. Cl. H03M 13/05; G06F 11/10

(52) U.S. Cl. 714/752; 714/E11.032

(57) ABSTRACT

Various embodiments of the present invention are related to methods and apparatuses for decoding data, and more particularly to methods and apparatuses for decoding variably sized blocks of data in an LDPC decoder. For example, in one embodiment an apparatus includes a low density parity check decoder operable to perform decoding of a plurality of circulant sub-matrices from an H matrix, and a controller connected to the low density parity check decoder, operable to omit any of the plurality of circulant sub-matrices from the decoding if they do not contain user data.

### BACKGROUND

Various data transfer systems have been developed including storage systems, cellular telephone systems, and radio transmission systems. In each of the systems data is transferred from a sender to a receiver via some medium. For example, in a storage system, data is sent from a sender (i.e., a write function) to a receiver (i.e., a read function) via a storage medium. As information is stored and transmitted in the form of digital data, errors are introduced that, if not corrected, can corrupt the data and render the information unusable. The effectiveness of any transfer is impacted by any losses in data caused by various factors. Many types of error checking systems have been developed to detect and correct errors in digital data. For example, in perhaps the simplest system, a parity bit can be added to a group of data bits, ensuring that the group of data bits (including the parity bit) has either an even or odd number of ones. When using odd parity, as the data is prepared for storage or transmission, the number of data bits in the group that are set to one are counted, and if there is an even number of ones in the group, the parity bit is set to one to ensure that the group has an odd number of ones. If there is an odd number of ones in the group, the parity bit is set to zero to ensure that the group has an odd number of ones. After the data is retrieved from storage or received from transmission, the parity can again be checked, and if the group has an even parity, at least one error has been introduced in the data. At this simplistic level, some errors can be detected but not corrected.

The parity bit may also be used in error correction systems, including in LDPC decoders. An LDPC code is a parity-based code that can be visually represented in a Tanner graph 100 as illustrated in FIG. 1. In an LDPC decoder, multiple parity checks are performed in a number of check nodes 102, 104, 106 and 108 for a group of variable nodes 110, 112, 114, 116, 118, 120, 122, and 124. The connections (or edges) between variable nodes 110-124 and check nodes 102-108 are selected as the LDPC code is designed, balancing the strength of the code against the complexity of the decoder required to execute the LDPC code as data is obtained. The number and placement of parity bits in the group are selected as the LDPC code is designed. Messages are passed between connected variable nodes 110-124 and check nodes 102-108 in an iterative process, passing beliefs about the values that should appear in variable nodes 110-124 to connected check nodes 102-108. Parity checks are performed in the check nodes 102-108 based on the messages and the results are returned to connected variable nodes 110-124 to update the beliefs if necessary. LDPC decoders may be implemented in binary or non-binary fashion. In a binary LDPC decoder, variable nodes 110-124 contain scalar values based on a group of data and parity bits that are retrieved from a storage device, received by a transmission system or obtained in some other way. Messages in the binary LDPC decoders are scalar values transmitted as plain-likelihood probability values or log-likelihood-ratio (LLR) values representing the probability that the sending variable node contains a particular value. In a non-binary LDPC decoder, variable nodes 110-124 contain symbols from a Galois Field, a finite field GF(p^{k}) that contains a finite number of elements, characterized by size p^{k} where p is a prime number and k is a positive integer. Messages in the non-binary LDPC decoders are multi-dimensional vectors, generally either plain-likelihood probability vectors or LLR vectors.

The connections between variable nodes 110-124 and check nodes 102-108 may be presented in matrix form as follows, where columns represent variable nodes, rows represent check nodes, and a random non-zero element a(i,j) from the Galois Field at the intersection of a variable node column and a check node row indicates a connection between that variable node and check node and provides a permutation for messages between that variable node and check node:

$$H = [ \begin{matrix}a ( 1 , 1 ) & 0 & 0 & a ( 1 , 2 ) & 0 & a ( 1 , 3 ) & a ( 1 , 4 ) & 0 \\ 0 & a ( 2 , 1 ) & 0 & 0 & a ( 2 , 2 ) & 0 & 0 & a ( 2 , 3 ) \\ a ( 3 , 1 ) & 0 & a ( 3 , 2 ) & 0 & a ( 3 , 3 ) & a ( 3 , 4 ) & 0 & a ( 3 , 5 ) \\ 0 & a ( 4 , 1 ) & 0 & a ( 4 , 2 ) & 0 & 0 & a ( 4 , 3 ) & a ( 4 , 4 )\end{matrix} ]$$

By providing multiple check nodes 102-108 for the group of variable nodes 110-124, redundancy in error checking is provided, enabling errors to be corrected as well as detected. Each check node 102-108 performs a parity check on bits or symbols passed as messages from its neighboring (or connected) variable nodes. In the example LDPC code corresponding to the Tanner graph 100 of FIG. 1, check node 102 checks the parity of variable nodes 110, 116, 120 and 122. Values are passed back and forth between connected variable nodes 110-124 and check nodes 102-108 in an iterative process until the LDPC code converges on a value for the group of data and parity bits in the variable nodes 110-124. For example, variable node 110 passes messages to check nodes 102 and 106. Check node 102 passes messages back to variable nodes 110, 116, 120 and 122. The messages between variable nodes 110-124 and check nodes 102-108 are probabilities or beliefs, thus the LDPC decoding algorithm is also referred to as a belief propagation algorithm. Each message from a node represents the probability that a bit or symbol has a certain value based on the current value of the node and on previous messages to the node.

A message from a variable node to any particular neighboring check node is computed using any of a number of algorithms based on the current value of the variable node and the last messages to the variable node from neighboring check nodes, except that the last message from that particular check node is omitted from the calculation to prevent positive feedback. Similarly, a message from a check node to any particular neighboring variable node is computed based on the current value of the check node and the last messages to the check node from neighboring variable nodes, except that the last message from that particular variable node is omitted from the calculation to prevent positive feedback. As iterations are performed in the system, messages pass back and forth between variable nodes 110-124 and check nodes 102-108, with the values in the nodes 102-124 being adjusted based on the messages that are passed, until the values converge and stop changing or until processing is halted.

Data is typically processed by LDPC encoders and decoders in a fixed block size, with the associated H matrix adapted to this block size. When the amount of user data to be processed by an LDPC encoder and decoder is variable, the LDPC decoder still operates on the fixed block size, even if the data block processed by the LDPC decoder is not filled with data. In other words, the LDPC decoder always decodes on the full H matrix even if some of the associated data bits are not provided to the LDPC decoder. For example, when reading data from a storage system such as a hard disk drive, the sector size is larger at the outer edges of the disk and smaller at the inner edges. The LDPC decoder is designed with an H matrix based on the largest sector size, and decodes on the full H matrix even when operating on a smaller sector, so that some of the bits for the H matrix are not transmitted through the channel to the LDPC decoder. If the same number of local and global decoding iterations are performed in the LDPC decoder for a short sector as for a long sector, the relative decoding time for the short sector is greater than for the long sector. In order to reduce the relatively greater latency for decoding short sectors, the number of iterations may be reduced, at the expense of decoding accuracy, increasing the possibility that the LDPC will fail to converge on the correct data values.

A need remains for more efficient and accurate decoding of variably sized blocks of data in an LDPC decoder.

### BRIEF SUMMARY

Various embodiments of the present invention are related to methods and apparatuses for decoding data, and more particularly to methods and apparatuses for decoding variably sized blocks of data in an LDPC decoder. For example, in one embodiment an apparatus includes a low density parity check decoder operable to perform decoding of a plurality of circulant sub-matrices from an H matrix, and a controller connected to the low density parity check decoder, operable to omit any of the plurality of circulant sub-matrices from the decoding if they do not contain user data. In some embodiments, partially-filled circulants containing some user data are included in the decoding, which may include performing variable node updates and check node updates. The LDPC decoder may be a binary or multi-level decoder, and a layer or non-layer decoder. In some embodiments, multiple circulants are processed in parallel, and if neither circulant to be processed in parallel contains any user data, the local iteration may be skipped for both, saving at least a clock cycle.

This summary provides only a general outline of some embodiments according to the present invention. Many other objects, features, advantages and other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals may be used throughout several drawings to refer to similar components. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 depicts a Tanner graph of an example prior art LDPC code;

FIG. 2 depicts a block diagram of a read channel which may be used to retrieve or receive stored or transmitted data in accordance with various embodiments of the present invention;

FIG. 3 depicts a variable sector size LDPC decoder with a non-layer architecture in accordance with various embodiments of the present invention;

FIG. 4 depicts the concentration of missing bits in circulant sub-matrices at the end of an H matrix for a non-layer variable sector size LDPC decoder in accordance with various embodiments of the present invention;

FIG. 5 depicts the concentration of missing bits in circulant sub-matrices at the end of two halves of an H matrix for a variable sector size LDPC layer decoder in accordance with various embodiments of the present invention;

FIG. 6 depicts a variable sector size LDPC layer decoder in accordance with various embodiments of the present invention;

FIG. 7 depicts a flow diagram showing a method for variable sector size LDPC decoding in accordance with various embodiments of the present invention;

FIG. 8 depicts a storage system including a variable sector size LDPC decoder in accordance with some embodiments of the present invention;

FIG. 9 depicts a virtual storage system including a variable sector size LDPC decoder in accordance with some embodiments of the present invention; and

FIG. 10 depicts an example data transmission device including a variable sector size LDPC decoder in accordance with some embodiments of the present invention.

### DETAILED DESCRIPTION OF THE INVENTION

Various embodiments of the present invention are related to methods and apparatuses for decoding data, and more particularly to methods and apparatuses for decoding variably sized blocks of data in an LDPC decoder. The LDPC decoder that is adapted to decode variably sized blocks of data is referred to herein for convenience as a variable sector size LDPC decoder, although it is not limited to use with sources that store data in sectors. The variable sector size LDPC decoder is also referred to below simply as an LDPC decoder for brevity.

The methods and apparatuses for calculating parity checks disclosed herein are applicable to any LDPC decoder, including but not limited to binary and non-binary or multi-level decoders, with layered or non-layered decoding, where the data being decoded is grouped and where groups can be excluded from local decoding iterations. For example, the LDPC decoder may use, but is not limited to, quasi-cyclic LDPC codes in which the parity check H matrix is an array of circulant sub-matrices, cyclically shifted versions of identity matrices and null matrices with different cyclical shifts. In some embodiments, the H matrix is constructed based on the finite field GF(4) with 12 circulant rows and 108 circulant columns, and with each circulant being a 48×48 sub-matrix with the form:

$${P}_{i , j} = [ \begin{matrix}0 & α & 0 & … & 0 \\ 0 & 0 & α & … & 0 \\ ⋮ & ⋮ & ⋮ & ⋱ & ⋮ \\ 0 & 0 & 0 & … & α \\ α & 0 & 0 & … & 0\end{matrix} ]$$

For example, given the 12×108 H matrix of 48×48 circulants, the overall row length is 108×48 or 5184, and the overall column height is 12×48 or 576.

When the variable sector size LDPC decoder receives less than the full amount of data for which the H matrix was designed, it improves decoding performance by skipping processing of circulant sub-matrices that do not contain user data, also referred to herein as partial updating. User data is defined herein as data to be decoded by the LDPC decoder and for which parity bits have been provided, for example from an LDPC encoder. The term “user data” does not imply any particular source of the data to be decoded. The data provided to the variable sector size LDPC decoder is consolidated by circulants so that missing bits are efficiently grouped in circulants, which can then be omitted from local decoding iterations. In some embodiments, user data is data read from a magnetic storage medium and excludes sync marks, preambles, and other formatting data. By skipping processing of circulants that do not contain user data, the LDPC decoder uses less time to perform a local decoding iteration on the H matrix. Variable nodes and check nodes relating to the missing bit positions do not need to be iteratively updated during partial updating. By reducing the processing time for one local iteration, more local and global iterations can be performed in a given time, thus improving performance.

Circulants that are partially empty, which contain some user data but are not filled completely with user data, are included in the local decoding iteration and processed. Empty portions of these circulants are filled, for example, with zero values, and the corresponding LLR values are set, for example, to the maximum reliability levels. For example, in an LDPC decoder with four-bit LLR values assigning likelihoods from 0 to 15, the LLR values for the fill-in zero values is set in some embodiments to 15. Circulants are referred to herein as empty herein when they contain no user data, even if they are filled with zeros, and as partially empty when they contain some user data but are not full of user data, even when the portion of the circulant not containing user data is filled with zeros.

The possibility of decoding errors is also reduced in the variable sector size LDPC decoder. When zero-filled missing bit positions in the H matrix are decoded, even with their initial values and corresponding LLR values set to predetermined levels, they may introduce decoding errors due to the influence of wrong variable node messages with lower reliability on bits or symbols with high reliability. This may even prevent decoding convergence by reliability oscillation, in which LLR values oscillate and delay or prevent convergence. By omitting empty circulants from local decoding iterations, the possibility of decoding errors and convergence failure is reduced.

In some embodiments, the variable sector size LDPC decoder receives a signal or indication from the LDPC encoder enabling the LDPC decoder to identify the circulants that do not contain user data. For example, the amount of user data may be indicated, or the empty circulants may be identified, etc. The signal or indication may be provided in any suitable manner, for example by storing the information in preambles or headers before the data, enabling the read channel to recover the information as the data is read or received and to provide the information to the LDPC decoder. The LDPC decoder may also use the same mechanisms used in conventional read channels for determining data block length to identify the empty circulants and omit them from local decoding iterations.

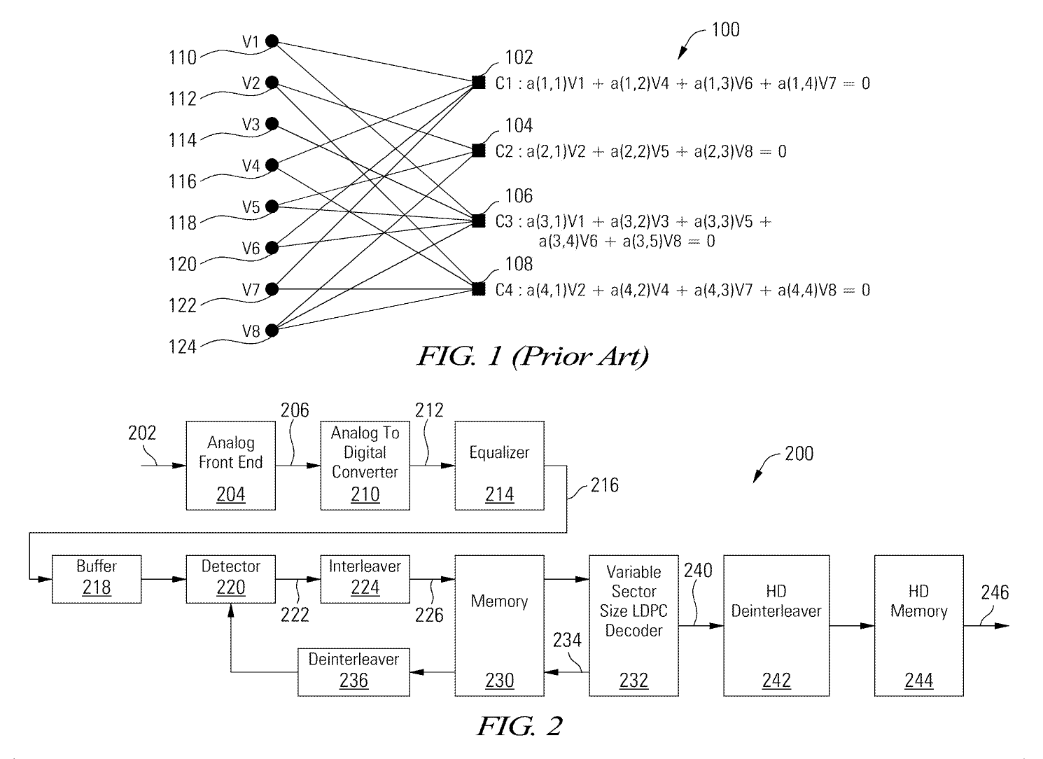

Although the variable sector size LDPC decoder disclosed herein is not limited to any particular application, several examples of applications are presented herein that benefit from embodiments of the present invention. Turning to FIG. 2, a read channel 200 is used to process an analog signal 202 and to retrieve user data bits from the analog signal 202 without errors. In some cases, analog signal 202 is derived from a read/write head assembly in a magnetic storage medium. In other cases, analog signal 202 is derived from a receiver circuit that is operable to receive a signal from a transmission medium. The transmission medium may be wireless or wired such as, but not limited to, cable or optical connectivity. Based upon the disclosure provided herein, one of ordinary skill in the art will recognize a variety of sources from which analog signal 202 may be derived.

The read channel 200 includes an analog front end 204 that receives and processes the analog signal 202. Analog front end 204 may include, but is not limited to, an analog filter and an amplifier circuit as are known in the art. Based upon the disclosure provided herein, one of ordinary skill in the art will recognize a variety of circuitry that may be included as part of analog front end 204. In some cases, the gain of a variable gain amplifier included as part of analog front end 204 may be modifiable, and the cutoff frequency and boost of an analog filter included in analog front end 204 may be modifiable. Analog front end 204 receives and processes the analog signal 202, and provides a processed analog signal 206 to an analog to digital converter 210.

Analog to digital converter 210 converts processed analog signal 206 into a corresponding series of digital samples 212. Analog to digital converter 210 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. Digital samples 212 are provided to an equalizer 214. Equalizer 214 applies an equalization algorithm to digital samples 212 to yield an equalized output 216. In some embodiments of the present invention, equalizer 214 is a digital finite impulse response filter circuit as is known in the art. Data or codewords contained in equalized output 216 may be stored in a buffer 218 until a data detector 220 is available for processing.

The data detector 220 performs a data detection process on the received input, resulting in a detected output 222. In some embodiments of the present invention, data detector 220 is a Viterbi algorithm data detector circuit, or more particularly in some cases, a maximum a posteriori (MAP) data detector circuit as is known in the art. In these embodiments, the detected output 222 contains log-likelihood-ratio (LLR) information about the likelihood that each bit or symbol has a particular value. Based upon the disclosure provided herein, one of ordinary skill in the art will recognize a variety of data detectors that may be used in relation to different embodiments of the present invention. Data detector 220 is started based upon availability of a data set in buffer 218 from equalizer 214 or another source.

The detected output 222 from data detector 220 is provided to an interleaver 224 that protects data against burst errors. Burst errors overwrite localized groups or bunches of bits. Because LDPC decoders are best suited to correcting errors that are more uniformly distributed, burst errors can overwhelm LDPC decoders. The interleaver 224 prevents this by interleaving or shuffling the detected output 222 from data detector 220 to yield an interleaved output 226 which is stored in a memory 230. The interleaved output 226 from the memory 230 is provided to a variable sector size LDPC decoder 232 which performs parity checks on the interleaved output 226, ensuring that parity constraints established by an LDPC encoder (not shown) before storage or transmission are satisfied in order to detect and correct any errors that may have occurred in the data during storage or transmission or during processing by other components of the read channel 200.

Multiple detection and decoding iterations may be performed in the read channel 200, referred to herein as global iterations. (In contrast, local iterations are decoding iterations performed within the LDPC decoder 232.) To perform a global iteration, LLR values 234 from the LDPC decoder 232 are stored in memory 230, deinterleaved in a deinterleaver 236 to reverse the process applied by interleaver 224, and provided again to the data detector 220 to allow the data detector 220 to repeat the data detection process, aided by the LLR values 234 from the LDPC decoder 232. In this manner, the read channel 200 can perform multiple global iterations, allowing the data detector 220 and LDPC decoder 232 to converge on the correct data values.

The LDPC decoder 232 also produces hard decisions 240 about the values of the data bits or symbols contained in the interleaved output 226 of the interleaver 224. For binary data bits, the hard decisions may be represented as 0's and 1's. For non-binary or multi-level symbols, in a GF(4) LDPC decoder, the hard decisions may be represented by field elements 00, 01, 10 and 11.

The hard decisions 240 from LDPC decoder 232 are deinterleaved in a hard decision deinterleaver 242, reversing the process applied in interleaver 224, and stored in a hard decision memory 244 before being provided to a user or further processed. For example, the output 246 of the read channel 200 may be further processed to reverse formatting changes applied before storing data in a magnetic storage medium or transmitting the data across a transmission channel.

Again, both layer decoding and non-layer decoding algorithms may be used in a variable sector size LDPC decoder, and example embodiments of each are disclosed below.

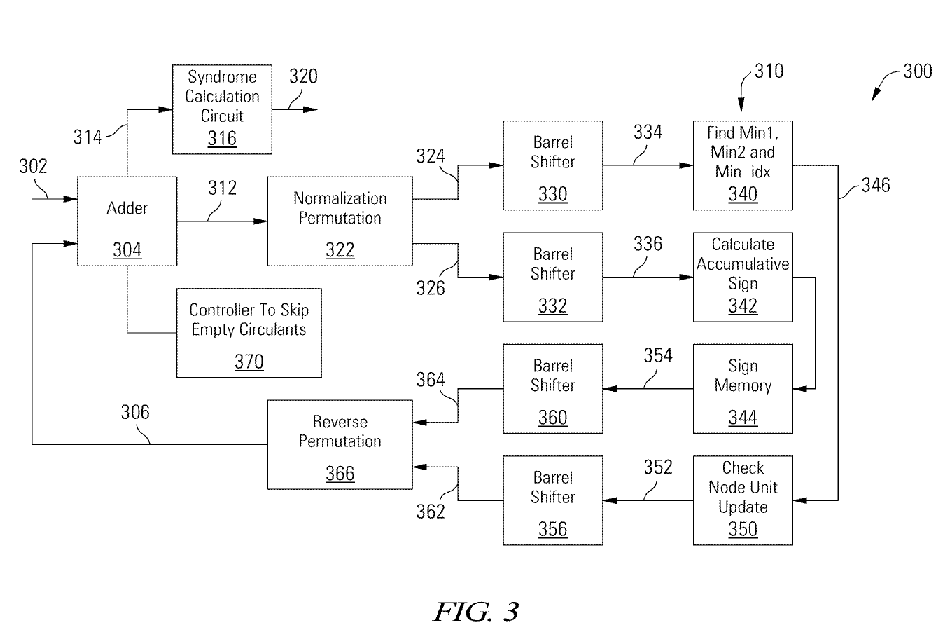

Turning now to FIG. 3, an example of a variable sector size LDPC decoder 300 with a non-layer architecture is disclosed in accordance with various embodiments of the present invention. The LDPC decoder 300 may be, but is not limited to, a min-sum based decoder in which check nodes calculate a minimum, next minimum and hard decision value based on incoming V2C or variable node message vectors. Furthermore, the LDPC decoder 300 disclosed herein is a multi-level or non-binary LDPC decoder. However, the variable sector size LDPC decoding is not limited to the min-sum based LDPC decoder 300 of FIG. 3, and any LDPC algorithm for decoding binary or multi-level data may be adapted to skip empty circulants to account for variable sector sizes.

The LDPC decoder 300 is provided with an input 302, for example containing hard decisions and corresponding LLR values generated by a data detector. The input 302 is provided to an adder 304 or variable node processor, which updates the perceived value of each bit or symbol based by adding values from the input 302 with C2V messages 306 or check node messages from a check node processor 310. The adder 304 generates V2C messages 312 or variable node messages for neighboring check nodes. The adder 304 also provides total LLR values 314 to a syndrome calculation circuit 316 to generate hard decisions 320 based on the argminₐ of the total LLR values. The syndrome calculation circuit 316 multiplies the codeword (data values corrected in the LDPC decoder 300) by the parity check H matrix to generate a syndrome or result vector. If the syndrome is a zero-valued vector, the codeword is correct and is provided as the hard decision 320.

The V2C messages 312 from the adder 304 are provided to normalization and permutation circuit 322. The normalization and permutation circuit 322 normalizes the soft LLR values in the V2C messages 312 by subtracting the minimum of the soft LLR values from the remaining soft LLR values. The normalization and permutation circuit 322 also arranges non-zero elements in each circulant of the H matrix according to the parity check equation implemented by the LDPC decoder 300, rearranging the updated values in the V2C messages 312 to prepare for the check node update. The normalization and permutation circuit 322 also applies the permutations specified by the non-zero elements of the H matrix. In a GF(4) embodiment, the four elements 0-3 of the Galois Field are 0, 1, α, α². The permutation applied by normalization and permutation circuit 322 is multiplication in the Galois Field. Element 2 (α) multiplied by element 1 (1) equals α×1 or α, which is element 2. Similarly, element 2×2=α×α=α², which is element 3. Element 2×3=α×α²=1, which is element 1. Thus, element 2 multiplied by 1, 2 and 3 results in elements 2, 3, and 1, which are permutations of elements 1, 2 and 3.

The normalized LLR values 324 and 326 from the normalization and permutation circuit 322 are provided to barrel shifters 330 and 332, respectively, which shifts the symbol values in the normalized LLR values 324 and 326 to generate the next circulant sub-matrix, yielding shifted LLR values 334 and 336.

A min-finder circuit 340 in the check node processor 310 calculates the minimum sub-message min₁(d), the index idx(d) of min₁(d), and the sub-minimum sub-message min₂(d), or minimum of all sub-messages excluding min₁(d), for each nonzero symbol d in the Galois Field based on all extrinsic V2C messages from neighboring variable nodes in the shifted LLR values 334. In other words, the sub-messages for a particular symbol d are gathered from messages from all extrinsic inputs, and the min₁(d), idx(d) and min₂(d) is calculated based on the gathered sub-messages for that symbol d. For a Galois Field with q symbols, the check node will calculate the min₁(d), idx(d) and min₂(d) sub-message for each of the q−1 non-zero symbols in the field except the most likely symbol.

The shifted LLR values 336 are also provided to an accumulative sign calculation circuit 342 which calculates the accumulative sign for the shifted LLR values 336 and provides them to a sign memory 344, which stores the sign value of each non-zero element of the H matrix.

The min value information 346 from the min-finder circuit 340 is provided to a check node unit update circuit 350, which generates C2V message values 352. The check node unit update circuit 350 selects either the min₁(d) or min₂(d) as the C2V message value 352 such that only extrinsic values are selected. If the current column index is equal to the index of the minimum value, meaning that the C2V message is being prepared for a variable node that provided the min₁(d) value, then the value of the C2V message is the second minimum value min₂(d). Otherwise, the value of the C2V message is the first minimum value min₁(d). The sign 354 of the C2V message value 352 is the XOR of the cumulative sign and the current sign of the symbol. The C2V message values 352 and their signs 354 are provided to barrel shifters 356 and 360, which shift the C2V message values 352 and their signs 354 to yield shifted C2V message values 362 and shifted signs 364, respectively, shifting between circulant sub-matrices. The shifted C2V message values 362 and shifted signs 364 are combined and processed in a reverse permutation circuit 366, which reverses the permutation applied in normalization and permutation circuit 322 to yield C2V messages 306 to the adder 304.

Multiple local iterations may be performed in the LDPC decoder 300, circulating data between the adder 304 and the check node processor 310 repeatedly to improve the convergence of the data. A controller 370 controls the operation of the LDPC decoder 300, causing it to skip empty circulants during local iterations. The controller 370 may identify empty circulants in any suitable manner. For example, the controller 370 may receive an indication of the total amount of user data received to be decoded, and may make a determination based upon the size of the H matrix which circulants are empty. In other embodiments, the controller 370 may receive a control signal indicating which circulants are empty, for example based on information contained in a preamble before the user data being decoded.

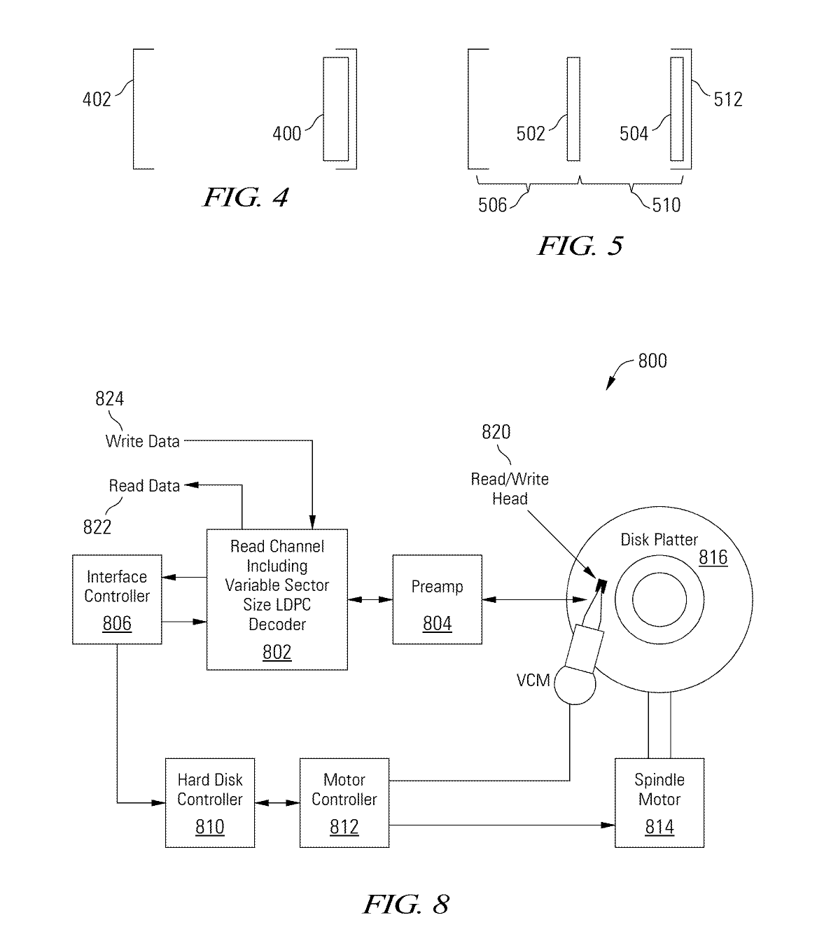

Turning to FIG. 4, skipping of circulants during local decoding iterations in a non-layer variable sector size LDPC decoder is enabled by concentrating missing hit positions in circulants 400 at the end of the H matrix 402. Variable node and check node calculations are performed iteratively column by column in the H matrix 402, and columns of circulants 400 that do not contain user data, or which are filled with missing bit positions, are skipped or omitted from local decoding iterations in the LDPC decoder. Any circulants containing some user data along with missing bit positions are included in the local decoding iterations.

Again, the non-layer LDPC decoding may be performed using any suitable technique or algorithms while skipping empty circulants. Several examples of LDPC decoding algorithms are disclosed below which may be suitable for use in a non-layer variable sector size binary LDPC decoder, including probability-based binary decoding and LLR-based min-sum binary decoding. The skipping of empty circulants does not affect the disclosed equations and algorithms. In the probability-based binary decoding, a codeword c=(c₁ c₂ . . . c_{N}) is mapped to a bipolar sequence x=(x₁ x₂ . . . x_{N}) to transmit, where x₁=2c₁−1. Let y=(y₁ y₂ . . . y_{N}) be the received sequence. Let

$$\begin{matrix}{p}_{l}^{0} = p ( {y}_{l} \vert {c}_{l} = 0 ) \\ = \frac{1}{\sqrt{π {N}_{0}}} {e}^{- {( {y}_{l} - 1 )}^{2} / {N}_{0}}\end{matrix}$$

$$\begin{matrix}{p}_{l}^{1} = p ( {y}_{l} \vert {c}_{l} = 1 ) \\ = \frac{1}{\sqrt{π {N}_{0}}} {e}^{- {( {y}_{l} + 1 )}^{2} / {N}_{0}}\end{matrix}$$

$${f}_{l}^{0} = \frac{{p}_{l}^{0}}{{p}_{l}^{0} + {p}_{l}^{1}}$$

$${f}_{l}^{1} = \frac{{p}_{l}^{1}}{{p}_{l}^{0} + {p}_{l}^{1}}$$

Let qₘₗ^{x} be the conditional probability that the transmitted code bit cₗ has value x, given the checksums computed based on the check vectors other than in. Let rₘₗ^{x} be the conditional probability that the check sum is satisfied, given that cₗ=x (0 or 1) and the other code bits have a separable distribution. The decoding algorithm is as follows:

1. Initialization:

$$\begin{matrix}{q}_{ml}^{0} = {f}_{l}^{0} \\ = \frac{{p}_{l}^{0}}{{p}_{l}^{0} + {p}_{l}^{1}}\end{matrix}$$

$$\begin{matrix}{q}_{ml}^{1} = {f}_{l}^{1} \\ = \frac{{p}_{l}^{1}}{{p}_{l}^{0} + {p}_{l}^{1}}\end{matrix}$$

2. Iterative Processing:
a. Horizontal step:

$${r}_{ml}^{0} = \frac{1}{2} ( 1 + {\prod }_{{l}^{′} ∈ N ( m ) \backslash l} ( {q}_{{ml}^{′}}^{0} - {q}_{{ml}^{′}}^{1} ) )$$

$${r}_{ml}^{1} = \frac{1}{2} ( 1 - {\prod }_{{l}^{′} ∈ N ( m ) \backslash l} ( {q}_{{ml}^{′}}^{0} - {q}_{{ml}^{′}}^{1} ) )$$

b. Vertical step:

$${q}_{ml}^{0} = {α}_{ml} {f}_{l}^{0} {\prod }_{{m}^{′} ∈ M ( l ) \backslash m} {r}_{{m}^{′} l}^{0}$$

$${q}_{ml}^{1} = {α}_{ml} {f}_{l}^{1} {\prod }_{{m}^{′} ∈ M ( l ) \backslash m} {r}_{{m}^{′} l}^{1}$$

Where αₘₗ is a normalization factor such that qₘₗ⁰+qₘₗ¹=1.

qₗ⁰=αₗfₗ⁰Π_{m′εM(l)}r_{m′l}⁰

qₗ¹=αₗfₗ¹Π_{m′εM(l)}r_{m′l}¹

Where αₗ is a normalization factor such that qₗ⁰+qₗ¹=1.
c. Hard decision and stopping criterion test:

ĉₗ=0 if qₗ⁰>qₗ¹

ĉₗ=1 otherwise

If H·ĉ=0 over GF(2), where \hat{x}εGF(2)^{N}, the decoding process is finished with ĉ as the decoder output; otherwise, repeat step 2 until the maximum iteration number.

The LLR-based min-sum binary LDPC decoding may be performed as disclosed below, in a circuit such as that in FIG. 3. The input 302 to the adder 304 referred to as Fₙ, and input C2V message 306 is referred to as Lₘₗ.

Define:

$${F}_{l} = ln \frac{{f}_{l}^{0}}{{f}_{l}^{1}}$$

$${L}_{ml} {=}^{Δ} ln \frac{{r}_{ml}^{0}}{{r}_{ml}^{1}}$$

$${Z}_{ml} {=}^{Δ} ln \frac{{q}_{ml}^{0}}{{q}_{ml}^{1}}$$

$${Z}_{l} {=}^{Δ} ln \frac{{q}_{l}^{0}}{{q}_{l}^{1}}$$

1. Initialization:

$${F}_{l} = \frac{4}{{N}_{0}} {y}_{l} , \\ where$$

$$\frac{4}{{N}_{0}}$$

can be omitted

Zₘₗ=Fₗ

2. Iterative Processing
a. Horizontal step performed in min-finder circuit 340 and accumulative sign calculation circuit 342:

$${L}_{ml} = {\prod }_{{l}^{′} ∈ N ( m ) \backslash l} sgn ( {Z}_{{ml}^{′}} ) \cdot {min}_{{l}^{′} ∈ N ( m ) \backslash l} \vert {Z}_{{ml}^{′}} \vert$$

b. Vertical step:

Zₘₗ=Fₙ+Σ_{m′εM(l)\m}L_{m′l}

Zₗ=Fₙ+Σ_{mεM(l)}Lₘₗ
c. Hard decision and stopping criterion test:

ĉₗ=0 if Zₗ>0

ĉₗ=1 otherwise

If H·ĉ=0 over GF(2) as calculated in syndrome calculation circuit 316, where \hat{x}εGF(2)^{N} the decoding process is finished with ĉ as the decoder output; otherwise, repeat step 2 until the maximum iteration number.

As disclosed above, the variable sector size decoding is also applicable to LDPC layer decoders. In some embodiments, the variable sector size LDPC layer decoder processes two circulants in parallel. To enable skipping of circulants during local decoding iterations in a variable sector size LDPC layer decoder, missing hit positions are concentrated as illustrated in FIG. 5 in circulants 502 and 504 at the ends of the first and second halves 506 and 510, respectively, of the H matrix 512. Variable node and check node calculations are performed iteratively column by column in the H matrix 512, with each of the parallel paths in the LDPC layer decoder processing circulants from separate halves 506 and 510 of the H matrix 512. If missing bits are concentrated equally in the circulants 502 and 504, both circulants 502 and 504 with no user data bits are omitted from local decoding iterations, saving the clock cycle in which the two circulants 502 and 504 would otherwise have been processed as well as reducing the possibility of oscillator and other errors. In the cases that one (e.g., 502) of the two circulants 502 and 504 does contain some user data while the other (e.g., 504) does not, the circulant 502 containing some user data is included in the local decoding iterations, and the circulant 504 with no user data is skipped. Thus, although the clock cycle cannot be saved, the possibility of errors is reduced during local iterations. Notably, although only two circulants 502 and 504 with missing bits are illustrated, more than one circulant in each half 506 and 510 of the H matrix 512 may be either partially or completely missing user data bits, with missing user data bits concentrated as much as possible in full circulants starting from the ends of each half 506 and 510 of the H matrix 512.

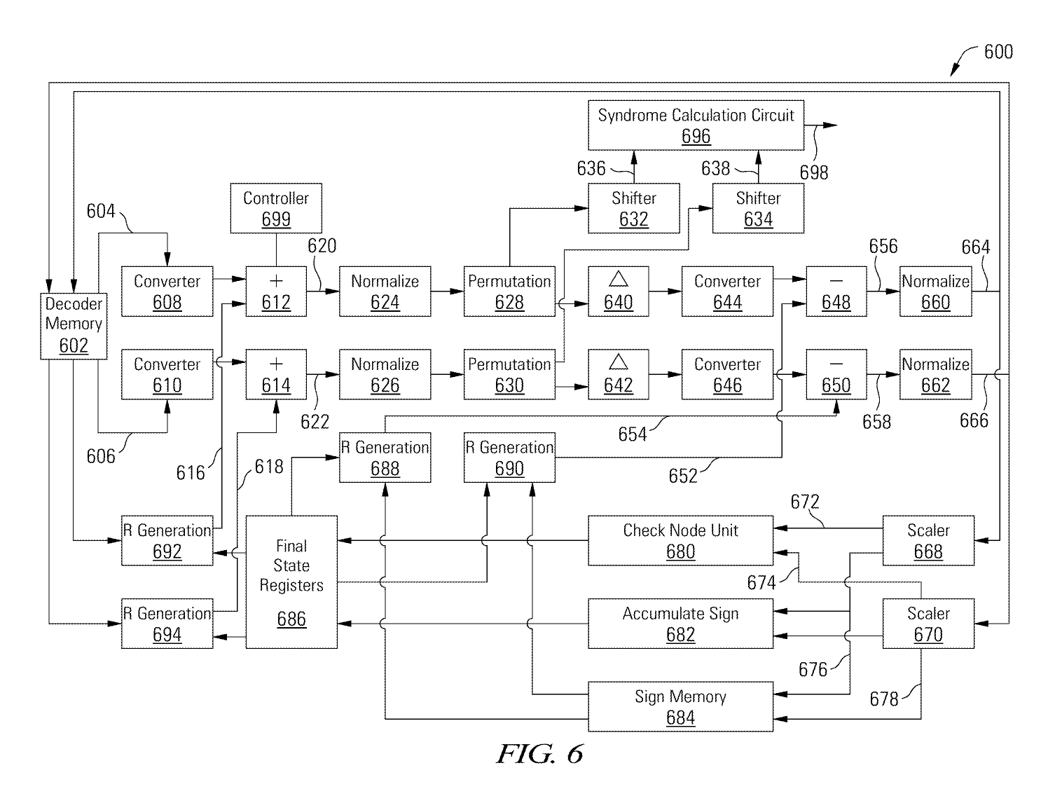

Turning now to FIG. 6, an example of a variable sector size LDPC layer decoder 600 is disclosed in accordance with various embodiments of the present invention. In the LDPC layer decoder 600, the parity check H matrix of the LDPC code is partitioned into L layers, with the H matrix being processed row by row and the circulants being processed layer by layer. As the rows are processed, the column results are updated based on each row result. Layered decoding can reduce the time to converge on a result in the decoder in some cases.

A decoder memory 602 in the LDPC layer decoder 600 stores soft LLR input values, Q values, and soft LLR output P values. The decoder memory 602 is a ping pong memory, consisting in some embodiments of 16 banks with each bank having size 54×264. The decoder memory 602 provides Q values 604 and 606 of the connected layer of the variable node to converters 608 and 610, respectively, each based on a different circulant being processed. In a GF(4) embodiment, the Q values 604 and 606 each consist of one hard decision and three soft LLR values.

The converters 608 and 610 convert the Q values from a format containing, a hard decision and three soft LLR values to a format containing four soft LLR values, with the information being equivalent in the two formats. Adders 612 and 614 add the connected layer's Q value (converted by converters 608 and 610) to the connected layer's R value 616 and 618 of each symbol of a circulant respectively, yielding the soft LLR values 620 and 622 of each symbol. In an embodiment with GF(4), each adder 612 and 614 consists of four adders each, adapted to add the connected layer's Q value with the connected layer's R value of each symbol of a circulant respectively to obtain the soft LLR values 620 and 622 of each symbol.

The soft LLR values 620 and 622 of each symbol are provided to normalizers 624 and 626, which compare the four values in each of the soft LLR values 620 and 622 to identify the minimum of each, and which subtract that minimum from the other three soft LLR values, thereby normalizing each of the soft LLR values 620 and 622 to their respective minimum.

The normalized variable node LLR values from normalizers 624 and 626 are provided to permutation circuits 628 and 630, which rearrange the variable node updated values to prepare for the check node update and apply the permutations specified by the non-zero elements of the H matrix. Again, in a GF(4) embodiment, the four elements 0-3 of the Galois Field are 0, 1, α, α². The permutation applied by permutation circuits 628 and 630 is multiplication in the Galois Field. Element 2 (α) multiplied by element 1 (1) equals α×1 or α, which is element 2. Similarly, element 2×2=α×α=α², which is element 3. Element 2×3=α×α²=1, which is element 1. Thus, element 2 multiplied by 1, 2 and 3 results in elements 2, 3, and 1, which are permutations of elements 1, 2 and 3. In the parity check calculation in the LDPC layer decoder 600, each hard decision value is multiplied by the non-zero elements (1, 2, or 3) of the H matrix, and the results are XORed together.

Shifters 632 and 634 process the output of permutation circuits 628 and 630 to shift the soft LLR values back to column order to yield soft LLR outputs 636 and 638, which are provided to a syndrome calculation circuit 696, which generates hard decisions 698 as the output of LDPC layer decoder 600. Soft LLR outputs 636 and 638 may also be used by a parity check calculator (not shown) to determine when data has converged in the LDPC layer decoder 600, as disclosed in U.S. patent application Ser. No. 13/227,416, filed Sep. 7, 2011 for a “Multi-Level LDPC Layer Decoder”, which is incorporated herein by reference for all purposes. Shifters 632 and 634 are used to shift from row order to column order because the LDPC layer decoder 600 processes data in row order, but the output total soft LLR is ordered by column in order to subtract the input LLR which is in column order to get the extrinsic LLR value. Delta shifters 640 and 642 also process the output of permutation circuits 628 and 630, shifting the output of the permutation circuits 628 and 630 by the difference in the circulant shift numbers of the current layer and the connected layer. In a given column there are circulants with different shift numbers, and the delta shifters 640 and 642 compensate for the different shift numbers of the current layer and the connected layer.

The output of delta shifters 640 and 642 is provided to converters 644 and 646 which convert from the format containing one hard decision and three soft LLR values back to the format containing four soft LLR values. Subtractors 648 and 650 then subtract the R values 652 and 654 of the symbols of the current layer from the soft LLR P values provided by converters 644 and 646 to obtain Q values 656 and 658 of the symbols of the current layer. The Q values 656 and 658 of the symbols of the current layer are then normalized in normalizers 660 and 662, which compare the four elements in each of the Q values 656 and 658 to identify the minimum of each, and which subtract that minimum from the other three elements of the Q values 656 and 658, thereby normalizing each of the Q values 656 and 658 to their respective minimum. The normalized Q values 664 and 666 are provided to the decoder memory 602 to update the Q values of the current layers, and also to scalers 668 and 670 to obtain the new Q values to perform the check node to variable node update.

Scalers 668 and 670 scale the normalized Q values 664 and 666 from the normalizers 660 and 662, yielding the new Q values 672 and 674, or absolute soft values, along with the Q values signs 676 and 678. The new Q values 672 and 674 and their signs 676 and 678 are provided to the check node unit 680 which finds the minimum value, second or next minimum value and the index of the minimum value. The new Q values signs 676 and 678 are also provided to a sign accumulator 682, which calculates and stores the cumulative sign for the current layer of the Q values 672 and 674, and to a sign memory 684 which stores the sign value of each non-zero element of the H matrix.

Final state registers 686 store the final state consisting of the minimum value, the second minimum value, the index of the minimum value, and cumulative sign of the current layer. These final state values are provided to two sets of R generators 688, 690, 692 and 694, which generate the R value for the connected layer or current layer based on the final state and current column index of the symbol. R generators 688 and 690 generate the R values for the current layer of the two circulants being processed, and R generators 692 and 694 generate the R values for the connected layer of the two circulants being processed. If the current column index is equal to the index of the minimum value, then the value of R is the second minimum value. Otherwise, the value of R is the minimum value of that layer. The sign of R is the XOR of the cumulative sign and the current sign of the symbol.

During operation of the LDPC layer decoder 600, as Q values and R values are iteratively circulated through the decoder 600, circulants which contain no user data symbols are omitted from the local iterations. When a pair of parallel circulants are both empty of user data symbols, they are both omitted from the local iterations, saving a clock cycle in some embodiments during the decoding operation.

A controller 699 in the LDPC layer decoder 600 is provided in some embodiments to control the decoding process, monitoring the convergence status and controlling the iterations, and most particularly in skipping decoding of circulants which contain no user data as disclosed above with respect to controller 370.

Again, LDPC layer decoding may be performed using any suitable technique or algorithms while skipping empty circulants. An example of an LDPC layer decoding algorithm is disclosed below which may be suitable for use in an LDPC layer decoder such as that illustrated in FIG. 6. The skipping of empty circulants does not affect the disclosed equations and algorithms. One input to the adders 612 and 614 is from the decoder memory 602, which is the V2C message from the previous layer, or Zₘₗ^{(prev)}. The other input to the adders 612 and 614 is the C2V message from the previous layer, or Lₘₗ^{(prev)}. The output 620 and 622 from adders 612 and 614 contains the total soft LLR value of the previous layer. The notation “(cur)” represents the current layer and “(prev)” represents the previous layer. The shifted output from delta shifters 640 and 642 is the total soft LLR value of the current layer, or Zₗ^{(cur)}. One input to subtractors 648 and 650, provided by converters 644 and 646, is the total soft LLR value of current layer, or Zₗ^{(cur)}. The other input is from check node update, which is the C2V message of the current layer, or Lₘₗ^{(cur)}. The result 656 and 658 is the V2C message of the current layer, or Zₘₗ^{(cur)}.

1. Initialization:

$${F}_{l} = \frac{4}{{N}_{0}} {y}_{l} , \\ where$$

$$\frac{4}{{N}_{0}}$$

can be omitted

Zₘₗ=Fₗ

2. Iterative Processing
a.

Zₗ^{(cur)}=(Zₘₗ^{(prev)}+Lₘₗ^{(prev)})_{shift}
b.

Zₘₗ^{(cur)}=Zₗ^{(cur)}−Lₘₗ^{(cur)}
c. (Performed in check node unit 680, sign accumulator 682 and sign memory 684)

$${L}_{ml} = {\prod }_{{l}^{′} ∈ N ( m ) \backslash l} sgn ( {Z}_{{ml}^{′}} ) \cdot {min}_{{l}^{′} ∈ N ( m ) \backslash l} \vert {Z}_{{ml}^{′}} \vert$$

d. Hard decision and stopping criterion test:

ĉₗ=0 if Zₗ>0

ĉₗ=1 otherwise

If H·ĉ=0 over GF(2), where \hat{x}εGF(2)^{N}, the decoding process is finished with ĉ as the decoder output; otherwise, repeat step 2 until the maximum iteration number.

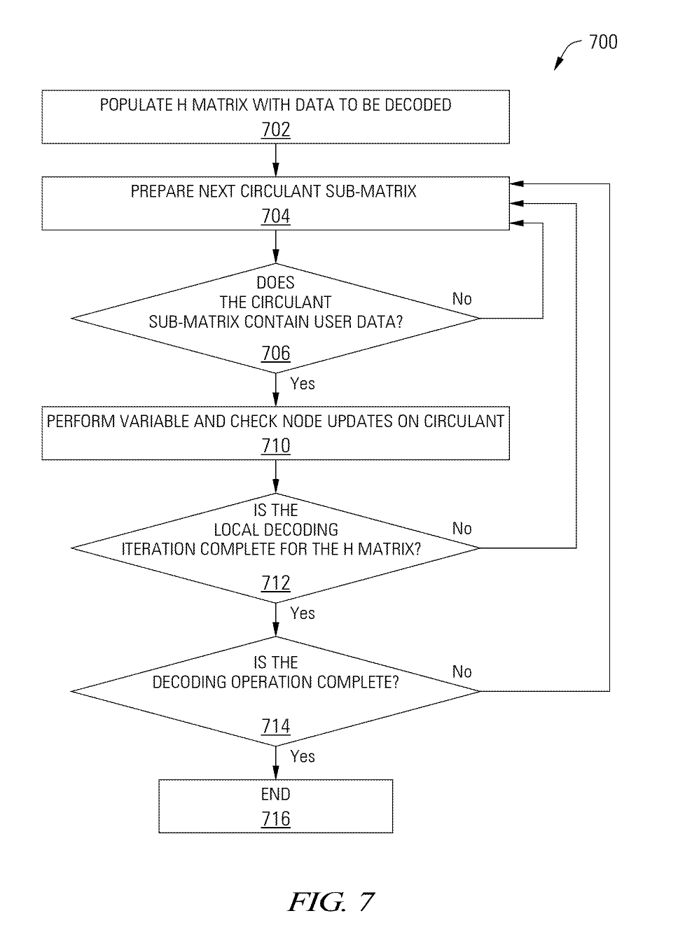

Turning to FIG. 7, a flow diagram 700 depicts a method for LDPC decoding of variable sector size data in accordance with various embodiments of the present invention. The method of FIG. 7, or variations thereof, may be performed in data decoding circuits such as those illustrated in FIGS. 3-6. Following flow diagram 700, the H matrix is populated with data to be decoded. (Block 702) Populating the H matrix may include receiving the data to be decoded corresponding to the H matrix. For a short sector, some of the H matrix may be missing user data bits. Circulants that contain some user data but are not full are zero-filled with maximum LLR values assigned to the zero values. Circulants that contain no user data will be skipped during local iterations, but may be zero-filled as well or may simply be omitted from the LDPC decoder memory. The next circulant sub-matrix is prepared for variable node and check node updates. (Block 704) The “next” circulant may be the first circulant in the H matrix when starting a local decoding iteration. Preparing the next circulant may be performed, for example, by barrel shifting V2C messages and C2V messages from one circulant to the next. A determination is made as to whether the circulant to be updated contains user data. (Block 706) If not, the next circulant is prepared and processing continues. (Block 704) If the circulant does contain user data, variable node and check node updates are performed on the circulant. (Block 710) The manner and timing of variable and check node updates is dependent on the type of variable sector size LDPC decoder, and may be performed as disclosed in various examples above or in other variations. Circulants may also be processed in parallel, as disclosed above with respect to FIG. 6. A determination is made as to whether the local decoding iteration is complete for the H matrix. (Block 712) If not, the next circulant is prepared and processing continues. (Block 704) If so, a determination is made as to whether the decoding operation is complete. (Block 716) The decoding operation may be determined to be complete when the maximum number of local decoding iterations has been performed, or when data convergence is detected. If the decoding operation is not complete, the next circulant is prepared and processing continues. (Block 704) If it is, the decoding is ended. (Block 716) The syndrome calculation is performed and a hard decision is provided at the output of the LDPC decoder.

Although the variable sector size LDPC decoder disclosed herein is not limited to any particular application, several examples of applications are presented herein that benefit from embodiments of the present invention. FIG. 8 shows a storage system 800 including a read channel circuit 802 with a variable sector size LDPC decoder in accordance with some embodiments of the present invention. Storage system 800 may be, for example, a hard disk drive. Storage system 800 also includes a preamplifier 804, an interface controller 806, a hard disk controller 810, a motor controller 812, a spindle motor 814, a disk platter 816, and a read/write head assembly 820. Interface controller 806 controls addressing and timing of data to/from disk platter 816. The data on disk platter 816 consists of groups of magnetic signals that may be detected by read/write head assembly 820 when the assembly is properly positioned over disk platter 816. In one embodiment, disk platter 816 includes magnetic signals recorded in accordance with either a longitudinal or a perpendicular recording scheme.

In a typical read operation, read/write head assembly 820 is accurately positioned by motor controller 812 over a desired data track on disk platter 816. Motor controller 812 both positions read/write head assembly 820 in relation to disk platter 816 and drives spindle motor 814 by moving read/write head assembly 820 to the proper data track on disk platter 816 under the direction of hard disk controller 810. Spindle motor 814 spins disk platter 816 at a determined spin rate (RPMs). Once read/write head assembly 820 is positioned adjacent the proper data track, magnetic signals representing data on disk platter 816 are sensed by read/write head assembly 820 as disk platter 816 is rotated by spindle motor 814. The sensed magnetic signals are provided as a continuous, minute analog signal representative of the magnetic data on disk platter 816. This minute analog signal is transferred from read/write head assembly 820 to read channel circuit 802 via preamplifier 804. Preamplifier 804 is operable to amplify the minute analog signals accessed from disk platter 816. In turn, read channel circuit 802 decodes and digitizes the received analog signal to recreate the information originally written to disk platter 816. This data is provided as read data 822 to a receiving circuit. As part of decoding the received information, read channel circuit 802 processes the received signal using a variable sector size LDPC decoder. Such a variable sector size LDPC decoder may be implemented consistent with that disclosed above in relation to FIGS. 3-6. In some cases, the variable sector size LDPC decoding may be done consistent with the flow diagram disclosed above in relation to FIG. 7. A write operation is substantially the opposite of the preceding read operation with write data 824 being provided to read channel circuit 802. This data is then encoded and written to disk platter 816. It should be noted that various functions or blocks of storage system 800 may be implemented in either software or firmware, while other functions or blocks are implemented in hardware.

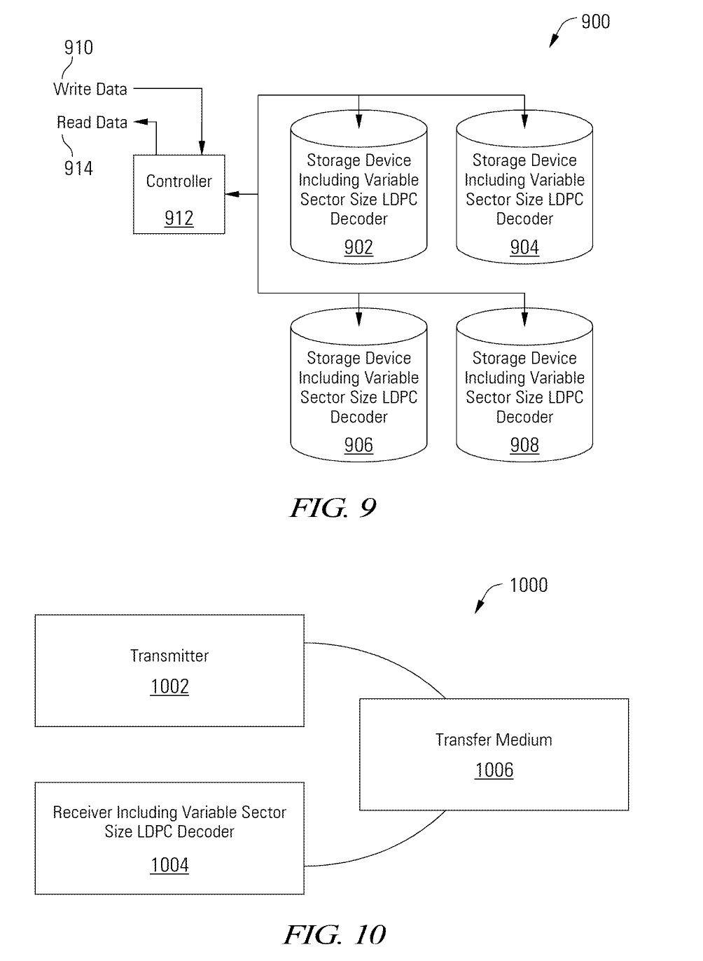

Turning to FIG. 9, a variable sector size LDPC decoder may be integrated into a virtual storage system such as a RAID (redundant array of inexpensive disks or redundant array of independent disks) based storage system 900 that increases stability and reliability through redundancy, combining multiple disks as a logical unit. Data may be spread across a number of disks 902, 904, 906, 908 included in the RAID storage system 900 according to a variety of algorithms and accessed by an operating system as if it were a single disk. For example, data may be mirrored to multiple disks 902-908 in the RAID storage system 900, or may be sliced and distributed across multiple disks 902-908 in a number of techniques. If a small number of disks (e.g., 902) in the RAID storage system 900 fail or become unavailable, error correction techniques may be used to recreate the missing data based on the remaining portions of the data from the other disks (e.g., 904-908) in the RAID storage system 900. The disks 902-908 in the RAID storage system 900 may be, but are not limited to, individual storage systems such as that disclosed above in relation to FIG. 8, and may be located in close proximity to each other or distributed more widely for increased security. In a write operation, write data 910 is provided to a controller 912, which stores the write data 910 across the disks 902-908, for example by mirroring or by striping the write data 910. In a read operation, the controller 912 retrieves the data from the disks 902-908, performing error correction using variable sector size LDPC decoding in either or both the controller 912 and the disks 902-908 and recreating any missing data where possible. The controller 912 then yields the resulting read data 914 as if the RAID storage system 900 were a single disk.

Turning to FIG. 10, a wireless communication system 1000 or data transmission device including a receiver 1004 with a variable sector size LDPC decoder is shown in accordance with some embodiments of the present invention. Communication system 1000 includes a transmitter 1002 that is operable to transmit encoded information via a transfer medium 1006 as is known in the art. The encoded data is received from transfer medium 1006 by receiver 1004. Receiver 1004 incorporates a variable sector size LDPC decoder. Such a variable sector size LDPC decoder may be implemented consistent with that disclosed above in relation to FIGS. 3-6. In some cases, the decoding may be done consistent with the flow diagram disclosed above in FIG. 7.

The variable sector size LDPC decoder disclosed herein enables a smaller number of decoding processing cycles, leading to a larger number of local iterations performed for short sector sizes, improving performance. Smaller decoding delays are achieved by skipping circulants, enabling a larger number of global iterations to be performed for short sector sizes, again improving performance. Faster convergence and less reliability value oscillation is achieved during decoding, improving performance and reducing power usage.

It should be noted that the various blocks discussed in the above application may be implemented in integrated circuits along with other functionality. Such integrated circuits may include all of the functions of a given block, system or circuit, or only a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the present invention provides novel methods and apparatuses for variable sector size LDPC decoding. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. An apparatus for decoding of variably sized blocks of low density parity check encoded data comprising:
a low density parity check decoder operable to perform decoding of a plurality of circulant sub-matrices from an H matrix; and
a controller connected to the low density parity check decoder, operable to omit empty ones of the plurality of circulant sub-matrices from the decoding, wherein the empty ones of the plurality of circulant sub-matrices contain no user data.

2. The apparatus of claim 1, wherein the controller is operable to include partially-filled ones of the plurality of circulant sub-matrices, wherein the partially filled ones of the plurality of circulant sub-matrices contain some user data but are not completely filled with user data.

3. The apparatus of claim 1, wherein the decoding comprises performing variable node updates and check node updates in the low density parity check decoder.

4. The apparatus of claim 3, wherein omitting the empty ones of the plurality of circulant sub-matrices comprises not performing the variable node updates and the check node updates for the empty ones of the plurality of circulant sub-matrices.

5. The apparatus of claim 1, wherein the low density parity check decoder comprises a binary decoder.

6. The apparatus of claim 1, wherein the low density parity check decoder comprises a multi-level decoder.

7. The apparatus of claim 1, wherein the low density parity check decoder comprises a non-layer decoder.

8. The apparatus of claim 2, wherein the low density parity check decoder comprises a layer decoder.

9. The apparatus of claim 8, wherein the low density parity check decoder is operable to process multiple ones of the plurality of circulant sub-matrices in parallel, and wherein the low density parity check decoder is operable to skip an entire local decoding iteration if none of the plurality of circulant sub-matrices to be processed in parallel during the local decoding iteration contain any user data.

10. The apparatus of claim 8, wherein the low density parity check decoder is operable to process multiple ones of the plurality of circulant sub-matrices in parallel, and wherein the low density parity check decoder is operable to omit the empty ones and to process the partially-filled ones of the plurality of circulant sub-matrices during a local decoding iteration.

11. The apparatus of claim 1, wherein the low density parity check decoder and the controller are implemented as an integrated circuit.

12. The apparatus of claim 1, wherein the low density parity check decoder and the controller are incorporated in a storage device.

13. The apparatus of claim 1, wherein the low density parity check decoder and the controller are incorporated in a storage system comprising a redundant array of independent disks.

14. The apparatus of claim 1, wherein the apparatus is incorporated in a data transmission device.

15. A method of decoding data in a low density parity check decoder, comprising:
populating an H matrix with the data; and
iteratively performing variable node updates and check node updates for a plurality of circulant sub-matrices of the H matrix, wherein ones of the plurality of circulant sub-matrices that contain none of the data are omitted from the variable node updates and the check node updates.

16. The method of claim 15, wherein ones of the plurality of circulant sub-matrices that contain some of the data but that are not full of the data are included in the variable node updates and the check node updates.

17. The method of claim 15, wherein a pair of the plurality of circulant sub-matrices are processed in parallel during a local iteration.

18. The method of claim 17, wherein if neither of the pair of the plurality of circulant sub-matrices contain any of the data, the local iteration is skipped.

19. The method of claim 17, wherein if a first one of the pair of the plurality of circulant sub-matrices contains at least some of the data and a second one of the pair of the plurality of circulant sub-matrices contains none of the data, the first one is included in the variable node updates and the check node updates and the second one is omitted from the variable node updates and the check node updates during the local iteration.

20. A storage system comprising:
a storage medium maintaining a data set;
a write head operable to magnetically record the data set to the storage medium;
a low density parity check decoder operable to perform decoding of a plurality of circulant sub-matrices from an H matrix; and
a controller connected to the low density parity check decoder, operable to omit empty ones of the plurality of circulant sub-matrices from the decoding, wherein the empty ones of the plurality of circulant sub-matrices contain no user data.
